(19) United States
(12) Patent Application Publication
(10) Pub. No.: US 2007/0190920 A1
(43) Pub. Date: Aug. 16, 2007

(54) Server cooling and exhaust appendage system

(75) Inventors: Don A. Gilliland, Rochester, MN (US); Cary M. Huettner, Rochester, MN (US)

Correspondence Address: CANTOR COLBURN LLP - IBM ROCHESTER DIVISION, 55 GRIFFIN ROAD SOUTH, BLOOMFIELD, CT, 06002, US

(73) Assignee: INTERNATIONAL BUSINESS MACHINES CORPORATION, ARMONK, NY (US)

(21) Appl. No.: 11/354,520

(22) Filed: Feb. 15, 2006

(51) Int. Cl. H05K 5/00

(52) U.S. Cl. 454/184

(57) ABSTRACT

Disclosed is a server cooling appendage including an entry fan containing structure that includes an entry fan, and an entry plenum connected to the entry fan containing structure and connectable to a server housing, wherein the entry fan containing structure and the entry plenum are disposed externally to a server housing. Also disclosed is an exit fan containing structure containing an exit fan, an exit plenum connected to the exit fan containing structure, wherein the exit fan containing structure and the exit plenum, are disposed externally to the server housing.

### FIELD OF THE INVENTION

This disclosure relates generally to server cooling and exhaust appendages, and more particularly to server cooling and exhaust appendages disposed externally to a server.

### BACKGROUND OF THE INVENTION

Over the past decade business servers have become an office staple. As server presence in the office has increased, space in which to house servers has become a concern. Predictably then, server technology has been directed to decreasing the physical size of the office server. With this decrease in size, servers have an increasingly limited internal space in which to house various hardware and software components. One such hardware component currently housed internally to the server is a cooling system. Though obviously necessary to server usage, internal cooling systems (with their standard fans and plenums) can occupy a fairly significant portion of internal server real estate, and be difficult to access for maintenance purposes. These and other similar issues are in conflict with the desire to continue to decrease server size.

Additionally, because keeping cooling system size to a minimum helps keep overall server size to a minimum, airflow components (such as fans and plenums) and acoustical components (such as acoustical foam) are sized and installed to take up as little space within the server as possible. By minimizing the size and number of airflow and acoustical components included within the server, available internal server real estate for other hardware and software components is increased at the expense of cooling system air flow and acoustics.

Therefore, there is a need for decreasing the internal server real estate occupied by a server cooling system, while increasing cooling system maintenance accessibility, and improving cooling system airflow and acoustics.

### BRIEF DESCRIPTION OF THE INVENTION

Disclosed is a server cooling and exhaust appendage system including an entry fan containing structure that includes an entry fan, wherein the entry fan containing structure is connectable to a rack system, and an entry plenum connected to the entry fan containing structure and connectable to a server housing, wherein the server housing and the rack system are connectable via the entry fan containing structure and the entry plenum, and wherein the entry fan containing structure and the entry plenum are disposed externally to the server housing. Also disclosed is an entry channel that is connectable to the entry fan containing structure and the rack system;

Additionally disclosed is an exit fan containing structure containing an exit fan, an exit channel that is connectable to the exit fan containing structure and the rack system, an exit plenum connected to the exit fan containing structure and connectable to the server housing, wherein the server housing and the exit channel are connectable via the exit fan containing structure and the exit plenum, and wherein the exit fan containing structure, exit plenum, and exit channel are disposed externally to the server housing, and an acoustical damping material contained within said entry plenum, and said exit plenum, said entry fan containing structure, and said exit fan containing structure.

### BRIEF DESCRIPTION OF THE FIGURES

The foregoing and other features and advantages of the present invention should be more fully understood from the following detailed description of illustrative embodiments taken in conjuncture with the accompanying Figures in which like elements are numbered alike in the several Figures:

FIG. 1 is a rear perspective view of a server cooling and exhaust appendage system;

FIG. 2 is a rear perspective view of the server cooling and exhaust appendage system; and

FIG. 3 is a side perspective view of an entry plenum including electromagnetic compatibility shielding.

### DETAILED DESCRIPTION

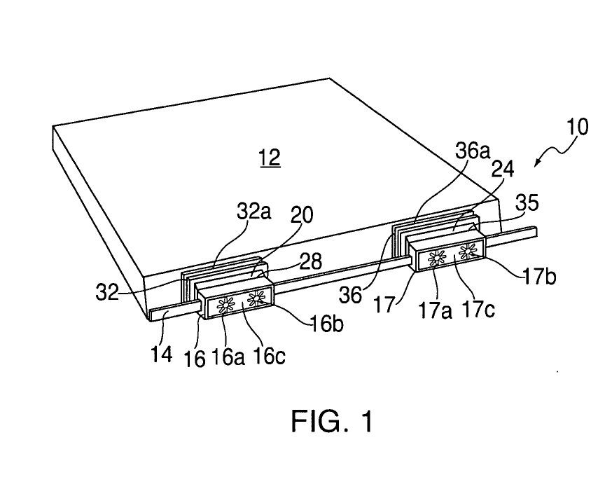

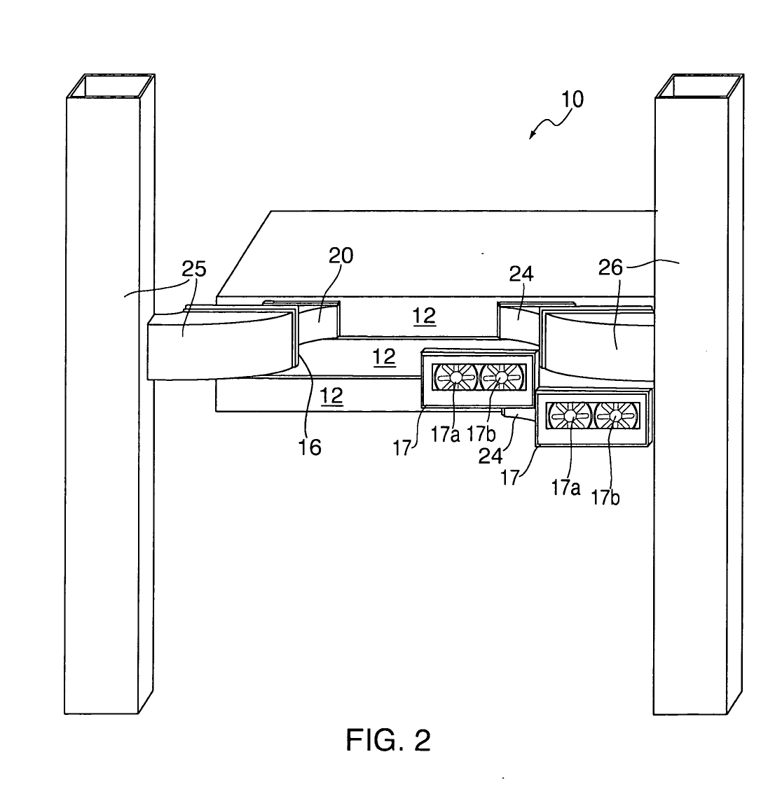

Referring to FIG. 1, a server cooling and exhaust appendage system 10 is illustrated. The server cooling and exhaust appendage system 10 allows for connectability between a server housing 12 (of a server) and a rack system (i.e. a plurality of associated server holding drawers), a portion of which being illustrated as a fan portion of the rack system 14. The server cooling and exhaust appendage system 10 is disposed externally to the server housing 12, and includes an entry fan containing structure and an exit fan containing structure. The entry fan containing structure is illustrated as entry fan container 16, and contains an entry fan or blower, illustrated as entry fans 16a-b. The exit fan containing structure is illustrated as exit fan container 17, and contains an exit fan or blower, illustrated as exit fans 17a-b. The server cooling and exhaust appendage system 10 also includes an entry plenum, illustrated as entry plenums 20, and an exit plenum, illustrated as exit plenum 24, wherein the entry plenum 20 is connected to the entry fan container 16, and the exit plenum 24 is connected to exit fan container 17. Additionally included, as shown in FIG. 2, is an entry channel 25 and an exit channel 26, which will be discussed in greater detail below.

The server cooling and exhaust appendage system 10 may stand alone in connection with the server housing 12, or, as mentioned above, allow connectability between the server housing 12 and rack system. With respect to connectability of the components of the server cooling and exhaust appendage system 10 to both the server housing 12 and rack system, connections involving the entry plenum will be discussed first. The entry plenum 20 includes an entry fan end 28 and a server entry end 32. The entry fan end 28 is the portion of entry plenum 20 that connects to the entry fan container 16, which may also be connectable to the rack system, possibly at the fan portion of the rack system 14, as shown in FIG. 1. The connection between the entry plenum 20 and the entry fan container 16 will be achieved via any means necessary, including unitarily constructing, snap fitting, screw fitting, or slide fitting. The connectability between the entry fan container 16 and the fan portion of the rack system 14 may also be achieved via any means necessary, including unitarily constructing, snap fitting, screw fitting, or slide fitting. Additionally, the fan portion of the rack system 14 may extend telescopically from the entry fan container 16, wherein it would then be connectable to the rack system via any means necessary, including snap fitting, screw fitting, or slide fitting.

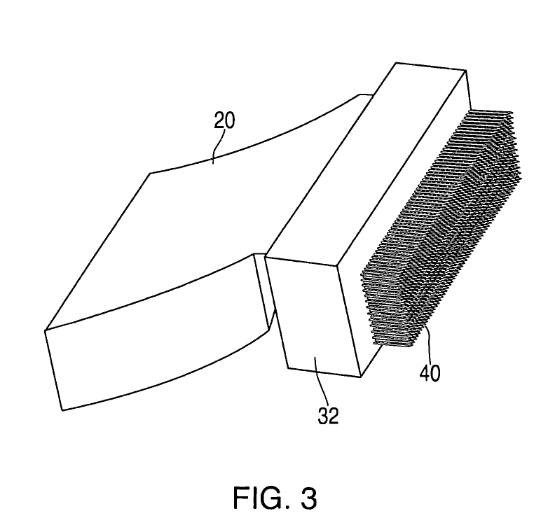

At the other end of the entry plenum 20, the server entry end 32 is the portion of the entry plenum 20 that is connectable to the server housing 12. This connectability to the server housing 12 may occur at any portion of the relative front, relative back, or either side of the server housing 12, and take place via a server entry port, illustrated as entry port 32a defined by the server housing 12. This connectability may be achieved via any means necessary, including unitarily constructing, snap fitting, slide fitting, or screw fitting. The entry port 32a and/or server entry end 32 of the entry plenums 20 may also include electromagnetic compatibility (EMC) perforations or EMC honeycomb shielding 40, as is shown extending from the server entry end 32 of the entry plenum 20 in FIG. 3. The perforations and, particularly, the honeycomb shielding 40, will have the effect of increasing acoustical attenuation at an area of connection between the entry plenum 20 and the server housing 12.

Similar to the entry plenum 20, the exit plenum 24 includes an exit fan end 35 and a server exit end 36. The exit fan end 35 is the portion of the exit plenum 24 that connects to the exit fan container 17. The connection between the exit fan end 35 and the exit fan container 17 will be achieved via any means necessary, including unitarily constructing, snap fitting, screw fitting, or slide fitting. The exit fan container 17 may also be connectable to the fan portion of the rack system 14, again via any means necessary, including unitarily constructing, snap fitting, screw fitting, or slide fitting. Additionally, the fan portion of the rack system 14 may extend telescopically from the exit fan container 17, wherein it would then be connectable to the rack system via any means necessary, including snap fitting, screw fitting, or slide fitting.

At the other end of the exit plenum 17, the server exit end 36 is the portion of the exit plenum 24 that is connectable to the server housing 12. This connectability to the server housing 12 may occur at any portion of the relative front, relative back, or either side, and take place via a server exit port, illustrated as exit port 36a defined by the server housing 12. This connectability may be achieved via any means necessary, including unitarily constructing, snap fitting, screw fitting, or slide fitting. The exit port 36a and/or server exit end 36 of the exit plenums 24 may also (like the entry plenum 20 above) include electromagnetic compatibility (EMC) perforations or EMC honeycomb shielding 40 (as shown extending from the server entry end 32 of the entry plenum 20 in FIG. 3). The perforations and, particularly, the honeycomb shielding 40, will have the effect of increasing acoustical attenuation at an area of connection between the exit plenum 24 and the server housing 12.

Referring to FIG. 2, it should be appreciated that the entry fan container 16 and the exit fan container 17 may be connectable to an entry channel 25 and an exit channel 26 respectively. This connectability may be achieved via any means necessary, including unitarily constructing, snap fitting, screw fitting, or slide fitting. Additionally, the entry channel 25 and the exit channel 26 are connectable to the rack system in general (connection not illustrated) via any means necessary, including unitarily constructing, snap fitting, screw fitting, or slide fitting. It should be appreciated that the entry channel 25 and exit channel 26 may each be connectable to multiple entry fan containers 16 and exit fan containers 17 when multiple servers are installed in a rack system, as is discussed below.

FIG. 2 also illustrates multiple server housings 12; each being connected to the entry fan container 16 and exit fan containers 17 via the entry plenum 20 and the exit plenums 24. In this Figure, the servers 12 are each installed into a rack system drawer section (not illustrated) that holds the server in place. When servers are installed in the drawer sections in this manner, exit plenums 24, as illustrated, may be shaped and directed to allow space for connectability of each exit fan container 17 and the fan portion of the rack system 14, while maintaining uniform position of the exit port 36a on each server housing 12. Entry plenums 20 may be shaped and directed similarly. In addition, it should be appreciated that both entry plenums 20 and exit plenums 24 may include telescoping features (not illustrated) that would allow at least partial removal of the server housings 12 from the above mentioned drawer sections. Similarly, adjustable guidance features (not illustrated) disposed at the server entry end 32 and/or server exit end 36 would allow a server pivoting action at the connection to the entry and exit plenums 20 and 24, aiding in at least partial removal of the server housings 12 from the above mentioned drawer sections. This adjustable guidance feature may associate with a side of the server housing 12 while the server entry end 32 and/or server exit end 36 connects to the server housing 12 at the relative front or back. The partial removal of the server housings 12 discussed here can be achieved while maintaining server housing 12 connection(s) with the plenums 20 and 24 because of the telescoping and adjustable guidance features.

As was mentioned above, all of these components of the server cooling and exhaust appendage system 10, including the entry fan container 16, the exit fan container 17, the entry plenum 20, the exit plenum 24, the entry channel 25, and the exit channel 26, are disposed externally to the server housing 12. The entry channel 25, and/or the exit channel 26 and/or the fan portion of said rack system 14 may also be disposed on a swing arm (not illustrated) that is mounted to the rack system and can rotate the entry channel, and/or the exit channel 26, and/or the fan portion of the rack system 14 (to which components of the server cooling appendage 10 may be connected) toward and away from a position for associating with the server housing 12 or other server cooling and exhaust appendage system 10 components not connected to the fan portion of the rack system 14. If disposed in this manner, this rotation may be advantageous in allowing the server housing 12 to connect with the server cooling and exhaust appendage system 10.

Once the server housing 12 and server cooling appendage 10 are connected, the entry fans 16a-b (which are configured to move air towards the server housing 12) cause cooling air to flow from the entry fan container 16, through the entry plenum 20, through the server entry port 32a, and into the server housing 12. If the entry fan container 16 is not connected to an entry channel 25, the cooling air is supplied from an environment surrounding the entry fan container 16, via an opening in the entry fan container 16, such as opening 16c, as shown in FIG. 1. If the entry fan container 16 is connected to an entry channel 25 a shown in FIG. 2, the cooling air is supplied from the entry channel 25.

The exit fans 17a-b on the other hand (which are configured to move/suck air out of the server housing 12) cause exhaust air to flow from the server housing 12 via the exit port 36a, into and through the exit plenum 24, and out into an atmosphere surrounding the exit fan container, via an opening in the exit fan container, such as opening 17c, as shown in FIG. 1, or into and through the exit channel 26, as shown in FIG. 2. The exit channel 26, if employed, is connectable to the rack system so as to transport and release exhaust from the exit plenum 24 to the environment outside of the rack system, wherein release of exhaust into this ambient environment may occur at the relative top/bottom or any side/portion of the rack system. Similarly, the entry channel 25, if employed, is connectable to the rack system so as to supply and transport cooling air from an environment outside for the rack system, wherein the entry channel 25 could supply this air via an opening (not illustrated) at the relative top/bottom or any side/portion of the rack system. It should be appreciated that all of the fans, plenums, and channels discussed above may be oversized for increased airflow into and out of the server housing 12 because there is no concern for internal server space.

The fans 16a-b and 18a-b discussed above may be powered via power sources disposed internally or externally to the server housing 12. A power source disposed internally to the server housing 12 may power the fans 16a-b and 18a-b via a cable hookup which extends from the server housing 12 to a fan actuator (not illustrated) associated with the fans 16a-b and 18a-b, wherein this cable may or may not be housed within any of the plenums 20 and 24. If the power source, such as a power distribution unit (PDU), is disposed externally to the server housing 12 (alleviating space within the server housing 12), this PDU may be positioned along the side of the rack system, and associate with the fan actuator, also via a cable hookup. Both internally and externally powered fans 16a-b and 18a-b may be controlled (i.e. be powered up or have their speeds controlled) via associations with the temperature control sensors within the server housing 12, wherein this association may take place via the cable extending from the server housing 12 to the fan actuator (internal power source), or via additional cables that link the fan actuator to the server housing 12 via a parallel port. If the fans 16a-b and 18a-b are large enough, as mentioned above, to cause a consistent airflow using an efficient amount of power, these fans may simply be set at a constant rate of speed for server cooling, eliminating the need for speed control.

In addition, it should be appreciated that disposal of the server cooling and exhaust appendage system 10 outside the server housing 12 allows easier fan (such as 16a-b and 18a-b) maintenance access than that which would be available if the cooling/exhaust system where disposed internal to the server housing 12. Also, because external fan containers, entry plenums, and exit plenums (such as entry and exit fan containers 16 and 17, entry plenum 20, and exit plenum 24) can be larger than their internal counterparts, these external containers and plenums have space to contain acoustical foam or other acoustical damping material, which can greatly increase acoustical attenuation.

While the invention has been described with reference to an exemplary embodiment, it should be understood by those skilled in the art that various changes may be made and equivalents may be substituted for elements thereof without departing from the scope of the invention. In addition, many modifications may be made to adapt a particular situation or substance to the teachings of the invention without departing from the scope thereof. Therefore, it is important that the invention not be limited to the particular embodiment disclosed as the best mode contemplated for carrying out this invention, but that the invention will include all embodiments falling within the scope of the apportioned claims. Moreover, unless specifically stated any use of the terms first, second, etc. do not denote any order or importance, but rather the terms first, second, etc. are used to distinguish one element from another.

What is claimed is:

1. A server cooling appendage comprising:
an entry fan containing structure including an entry fan, wherein said entry fan containing structure is connectable to a rack system;
an entry channel that is connectable to said entry fan containing structure and said rack system;
an entry plenum connected to said entry fan containing structure and connectable to a server housing, wherein said server housing is connectable to said entry fan containing structure and said entry plenum, and wherein said entry fan containing structure, said entry plenum, and said entry channel are disposed externally to said server housing;
an exit fan containing structure containing an exit fan;
an exit channel that is connectable to said exit fan containing structure and said rack system;
an exit plenum connected to said exit fan containing structure and connectable to said server housing, wherein said server housing and said exit channel are connectable via said exit fan containing structure and said exit plenum, and wherein said exit fan containing structure, said exit plenum, and said exit channel are disposed externally to said server housing; and
an acoustical damping material contained within said entry plenum, and said exit plenum, said entry fan containing structure, and said exit fan containing structure.

2. A server cooling appendage according to claim 1, wherein said entry fan containing structure is connectable to said rack system, and wherein said entry fan containing structure and said exit channel are connectable to said rack system via at least one of unitary construction, snap fitting, screw fitting, and slide fitting, and said exit fan containing structure is connectable to said exit channel via at least one of unitary construction, snap fitting and slide fitting.

3. A server cooling appendage according to claim 1, wherein said entry plenum and said exit plenum are connectable with said server housing via at least one of unitary construction, snap fitting, slide fitting, and screw fitting.

4. A server cooling appendage according to claim 2, wherein said entry fan containing structure is connectable to a fan portion of said rack system via at least one of unitary construction, snap fitting, screw fitting, and slide fitting.

5. A server cooling appendage according to claim 4, wherein said exit fan containing structure is connectable to said fan portion of said rack system via at least one of unitary construction, snap fitting, screw fitting, and slide fitting, and said exit channel is connectable to said fan portion of said rack system via at least one of unitary construction, snap fitting and slide fitting.

6. A server cooling appendage according to claim 1, wherein said exit channel is disposed upon a swing arm.

7. A server cooling appendage according to claim 5, wherein said exit channel is disposed upon a swing arm and connectable to said fan portion of said rack system, wherein said fan portion of said rack system is rotatable via said swing arm.

8. A server cooling appendage according to claim 1, wherein said acoustical damping material is an acoustical foam.

9. A server cooling appendage according to claim 1, wherein said entry plenum and said exit plenum include at least one of electromagnetic compatibility perforation and electromagnetic compatibility honeycomb shielding.

10. A server cooling appendage according to claim 1, wherein said entry fan and said exit fan are powered via a power source internal to said server housing.

11. A server cooling appendage according to claim 1, wherein said entry fan and said exit fan are powered via a power source external to said server housing.

12. A server cooling appendage according to claim 4, wherein said fan portion of said rack system extends telescopically from at least one of said exit fan container and said entry fan container, and connectable to said rack system via any means necessary, including snap fitting, screw fitting, or slide fitting.
